(19) United States
(12) Patent Application Publication
(10) Pub. No.: US 2026/0271420 A1
(43) Pub. Date: Sep. 10, 2026

(54) IMAGE SENSOR

(71) Applicant: Samsung Electronics Co., Ltd., Suwon-si (KR)

(72) Inventors: Haneul KIM, Suwon-si (KR); Jihyun KWAK, Suwon-si (KR); Jinyoung KIM, Suwon-si (KR); Chang Kyu LEE, Suwon-si (KR); HaeJung LEE, Suwon-si (KR); Jongmin JEON, Suwon-si (KR)

(73) Assignee: Samsung Electronics Co., Ltd., Suwon-si (KR)

(21) Appl. No.: 19/328,865

(22) Filed: Sep. 15, 2025

(30) Foreign Application Priority Data
Mar. 10, 2025 (KR) 10-2025-0030705

(51) Int. Cl. H10F 39/00

(52) U.S. Cl. CPC H10F 39/8063

(57) ABSTRACT

An image sensor according to at least one example embodiment includes a sensor substrate including a photoelectric conversion region; a spacer layer positioned on the sensor substrate; and a color separation lens layer positioned on the spacer layer, wherein the color separation lens layer includes a plurality of nano posts and a dielectric layer positioned between the plurality of nano posts, the nano post includes a first refraction layer and a second refraction layer, the second refraction layer is positioned along the bottom surface and the side surface of the first refraction layer, and the refractive index of the first refraction layer is larger than the refractive index of the second refraction layer.

### CROSS-REFERENCE TO RELATED APPLICATION

This application claims priority to and the benefit of Korean Patent Application No. 10-2025-0030705 filed with the Korean Intellectual Property Office on Mar. 10, 2025, the entire contents of which are incorporated herein by reference.

### BACKGROUND OF THE DISCLOSURE

### Field of the Disclosure

This disclosure relates to an image sensor.

### Description of the Related Art

An image sensor may be a semiconductor device that is configured to convert an optical image into an electric signal. Classifications of Image sensors may include a charge coupled device (CCD) type and a complementary metal oxide semiconductor (CMOS) type, and the CMOS type image sensors may be abbreviated as a CMOS image sensor (CIS). The CIS may have a plurality of pixels two-dimensionally arranged, and each of the pixels may include a photodiode (PD). In these cases, the photodiode may be configured to incident light into an electric signal.

Recently, attempts have been made to use a color separation lens layer instead of a color filter to improve a light utilization efficiency of the image sensor. The color separation lens layer separates the colors of the incident light using diffraction and/or refraction characteristics of light that differ depending on a wavelength, and may control a directionality for each wavelength depending on the refractive index and shape. The colors separated by the color separation lens layer may be transmitted to each corresponding pixel.

### SUMMARY OF THE DISCLOSURE

The present disclosure provides an image sensor including a fine nano post and a manufacturing method thereof.

An image sensor according to at least one example embodiment includes a sensor substrate including a photoelectric conversion region; a spacer layer on the sensor substrate; and a color separation lens layer spaced apart from the sensor substrate with the spacer layer between the sensor substrate and the color separation lens layer, wherein the color separation lens layer includes a plurality of nano posts and a dielectric layer between the plurality of nano posts, each of the plurality of nano posts include a first refraction layer and a second refraction layer, the second refraction layer is positioned along a bottom surface of the first refraction layer and a side surface of the first refraction layer, and a refractive index of the first refraction layer is larger than a refractive index of the second refraction layer.

An image sensor according to at least one example embodiment includes a sensor substrate including a photoelectric conversion region; a spacer layer above the sensor substrate; an intermediate layer above the spacer layer such that the spacer layer is between the intermediate layer and the sensor substrate; and a color separation lens layer above the intermediate layer such that the intermediate layer is between the color separation lens layer and the spacer layer, wherein the color separation lens layer includes a plurality of nano posts and a dielectric layer between the plurality of nano posts, the plurality of nano posts each include a first refraction layer and a second refraction layer, the second refraction layer covers a bottom surface and a side surface of the first refraction layer, and a refractive index of the first refraction layer is greater than a refractive index of the second refraction layer and a refractive index of the dielectric layer.

An image sensor according to at least one example embodiment includes a sensor substrate including a sensor substrate including a photoelectric conversion region; a spacer layer above the sensor substrate; and a color separation lens layer above the spacer layer such that the spacer layer is between the color separation lens layer and the sensor substrate, wherein the color separation lens layer includes a plurality of nano posts and a dielectric layer between the plurality of nano posts, each of the plurality of nano posts include a first refraction layer, the dielectric layer is on a bottom surface of the first refraction layer and on a side surface of the first refraction layer, and a distance between a bottom surface of the dielectric layer and the spacer layer is less than a distance between the bottom surface of the first refraction layer and the spacer layer.

The example embodiments include the image sensor including the fine nano posts and the method for manufacturing the same are provided.

### BRIEF DESCRIPTION OF THE DRAWINGS

FIG. 1 is an example block diagram of an image sensor according to at least one example embodiment.

FIG. 2 is a schematic view showing a pixel array structure of an image sensor of FIG. 1.

FIG. 3 is a cross-sectional view taken along a line I-I′ of FIG. 2.

FIG. 4 is a view illustrating the same region as FIG. 3 for at least one example embodiment.

FIG. 5 is a view illustrating the same region as FIG. 3 for at least one example embodiment.

FIG. 6 is a view illustrating the same region as FIG. 3 for at least one example embodiment.

FIG. 7 is a view illustrating the same region as FIG. 4 for at least one example embodiment.

FIG. 8 is a view illustrating the same region as FIG. 5 for at least one example embodiment.

FIG. 9 is a view illustrating the same region as FIG. 3 for at least one example embodiment.

FIG. 10 is a view illustrating the same region as FIG. 9 for at least one example embodiment.

FIG. 11 is a view illustrating the same region as FIG. 10 for at least one example embodiment.

FIG. 12 is a cross-sectional view schematically illustrating a structure of an image sensor.

FIG. 13 is a view illustrating a portion of a cross-section of a sensor substrate.

FIG. 14 and FIG. 15 are plan views showing an arrangement of pixels and an arrangement of light-sensitive cells corresponding to pixel regions in an image sensor according to the present embodiment.

FIG. 16 is a top plan view showing an arrangement of nano posts in a color separation lens layer of an image sensor according to the present embodiment.

FIG. 17 is an enlarged top plan view showing a partial region of FIG. 16.

FIG. 18 to FIG. 21 are cross-sectional views schematically showing a process of a manufacturing method of an image sensor according to at least one example embodiment.

FIG. 22 is a block configuration diagram for an electronic device including an image sensor according to at least one example embodiment.

### DETAILED DESCRIPTION

The present disclosure will be described more fully hereinafter with reference to the accompanying drawings, in which example embodiments of the disclosure are shown. As those skilled in the art would realize, the described embodiments may be modified in various different ways, all without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means viewing the object portion from the top, and the phrase “on a cross-section” means viewing a cross-section of which the object portion is vertically cut from the side.

Furthermore, terms such as “. . . unit,” “. . . module,” and “. . . block”, and/or terms describing unit configured to process at least one function or operation, unless indicated otherwise, may be embodied by (and/or included in) processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

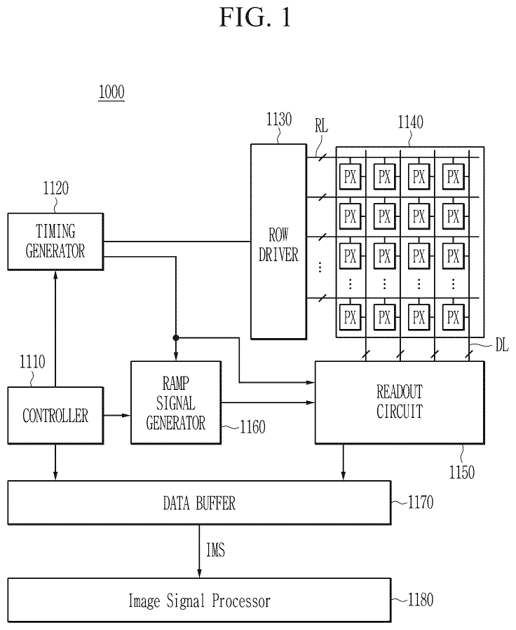

FIG. 1 is an example block diagram of an image sensor according to at least one example embodiment.

Referring to FIG. 1, an image sensor 1000 according to at least one example embodiment may include a controller 1110, a timing generator 1120, a row driver 1130, a pixel array 1140, a readout circuit 1150, a ramp signal generator 1160, a data buffer 1170, and an image signal processor 1180. In at least one example embodiment, the image signal processor 1180 may be positioned outside the image sensor 1000.

According to at least one example embodiment, the image sensor 1000 is configured to generate an image signal by converting light received from the outside into an electric signal. An image signal IMS may be provided to the image signal processor 1180.

The image sensor 1000 may be mounted on an electronic device having an image or light sensing function. For example, the image sensor 1000 may be mounted on electronic devices such as a camera, a smart phone, a wearable device, an Internet of Things (IoT) device, a home appliance, a tablet personal computer (PC), a personal digital Assistant (PDA), a portable multimedia player (PMP), a navigation, a drone, an advanced driver assistance system (ADAS), and/or the like. Alternatively, the image sensor 1000 may be mounted on an electronic device provided as a component in a vehicle, a piece of furniture, a manufacturing equipment, a door, various measuring instruments, and/or the like.

controller 1110 may control some of and/or all of the components 1120, 1130, 1150, 1160, and 1170 included in the image sensor 1000. The controller 1110 may also control the operation timing of each component 1120, 1130, 1150, 1160, and 1170 by using control signals. In at least one example embodiment, the controller 1110 may receive a mode signal indicating an imaging mode from an application processor, and may control the image sensor 1000 overall based on the received mode signal. For example, the application processor may determine the imaging mode of the image sensor 1000 based on various scenarios such as an illumination of an imaging environment, a resolution setting of a user, and a sensed or learned status, and provide the determined result to the controller 1110 as a mode signal. The controller 1110 may control a plurality of pixels of pixel array 1140 to output the pixel signal according to the imaging mode, the pixel array 1140 may output the pixel signal for each of the plurality of pixels or the pixel signal for some of the plurality of pixels, and the read-out circuit 1150 may sample and process the pixel signal received from the pixel array 1140. The timing generator 1120 may generate a signal that serves as a reference for the operation timing of the components of the image sensor 1000. The timing generator 1120 may control the timing of the row driver 1130, the read-out circuit 1150, and the ramp signal generator 1160. The timing generator 1120 may provide control signals to control the timing of the row driver 1130, the read-out circuit 1150, and the ramp signal generator 1160.

The pixel array 1140 may include a plurality of pixels PX, and a plurality of row lines RL and a plurality of column lines DL, each connected to the plurality of pixels PX. In at least one example embodiment, each pixel PX may include at least one or more photoelectric conversion devices. The photoelectric conversion device may detect an incident light and convert the incident light into an electric signal according to the amount of light, that is, a plurality of analog pixel signals. The photoelectric conversion device may be a photodiode, a pin diode, etc. Additionally, the photoelectric conversion device may be a single-photon avalanche diode (SPAD) applied to a 3D sensor pixel. The level of the analog pixel signal output from the photoelectric conversion device may be proportional to the amount of charge output from the photoelectric conversion device. That is, the level of the analog pixel signal output from the photoelectric conversion device may be determined according to the amount of light received within the pixel array 1140.

The plurality of row lines RL may extend in the first direction and be connected to the pixels PX arranged along the first direction. For example, the control signal output from the row driver 1130 to the row line RL may be transmitted to the gates of the transistors of the plurality of pixels PX connected to the corresponding row line RL. The column line DL may extend in the second direction intersecting the first direction and be connected to the pixels PX arranged along the second direction. The plurality of pixel signals output from the plurality of pixel PX can be transmitted to the read-out circuit 1150 through a plurality of column lines DL.

The row driver 1130 may generate a control signal for driving the pixel array 1140 in response to the control signal of the timing generator 1120 and provide the control signal to the plurality of pixels PX of the pixel array 1140 through the plurality of row lines RL. In at least one example embodiment, the row driver 1130 may control the pixel PX to detect the incident light by a row line unit. The row line unit may include at least one row line RL.

The read-out circuit 1150 may convert the pixel signal (or the electric signal) (e.g., the pixel signal received from the pixels PX connected to the selected row lines RL among the plurality of pixels PX) into a pixel value representing a light quantity in response to the control signal from the timing generator 1120. The read-out circuit 1150 may convert the pixel signal output through the corresponding column lines LL into the pixel value. For example, the read-out circuit 1150 may convert the pixel signal into the pixel value by comparing the ramp signal and the pixel signal. The pixel value may be an image data having a plurality of bits. In at least one example embodiment, the read-out circuit 1150 may include a selector, a plurality of comparators, and a plurality of counter circuits.

The ramp signal generator 1160 may generate a reference signal and transmit it to the read-out circuit 1150.

The ramp signal generator 1160 may include a current source, a resistor, and a capacitor. The ramp signal generator 1160 may generate a plurality of ramp signals that rise or fall with a slope determined by a current size of a variable current source and/or a resistance value of a variable resistor by controlling the ramp voltage, which is the voltage applied to the ramp resistor, by controlling the current size of the variable current source or the resistance value of the variable resistor.

The data buffer 1170 may store the pixel values of the plurality of pixels PX connected to the selected column lines DL, which are transmitted from the read-out circuit 150, and output the stored pixel values in response to an enable signal from the controller 1110.

The image signal processor 1180 may perform the image signal processing on the image signals received from the data buffer 1170. For example, the image signal processor 1180 may receive the plurality of image signals from the data buffer 1170 and synthesize the received image signals to generate one image.

In at least one example embodiment, the plurality of pixels may be grouped in a format of M*N (M and N are each integers greater than or equal to 2) to form a single unit pixel group. The M*N format may be a format in which M items are listed in the arrangement direction of the column lines DL and N items are listed in the arrangement direction of the row lines RL. For example, one unit pixel group includes the plurality of pixels arranged in a 2*2 format, and one unit pixel group may output one analog pixel signal. The following embodiment is not limited to the single pixel, but may also be applied to the unit pixel group.

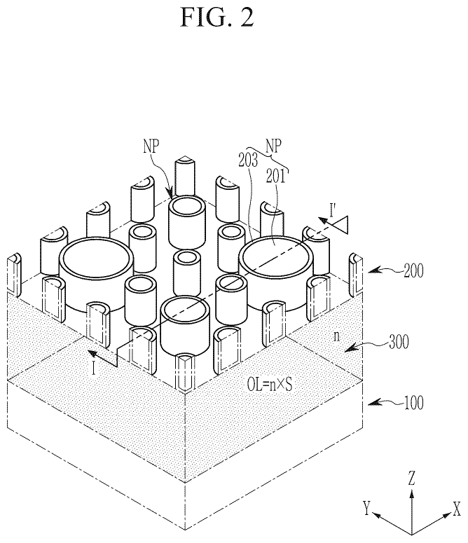

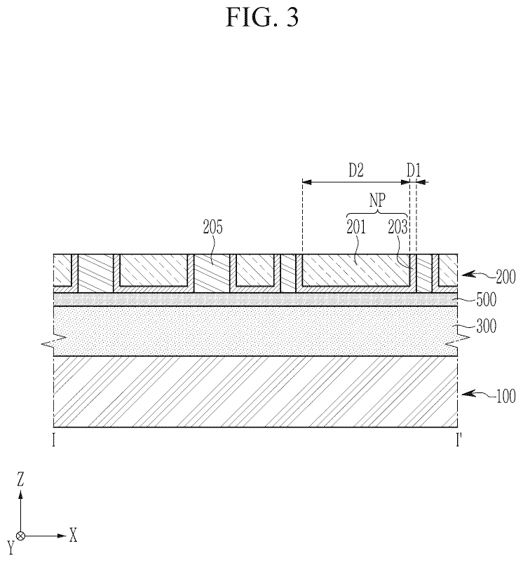

FIG. 2 is a schematic view showing a pixel array structure of the image sensor of FIG. 1. FIG. 3 is a cross-sectional view taken along a line I-I′ of FIG. 2.

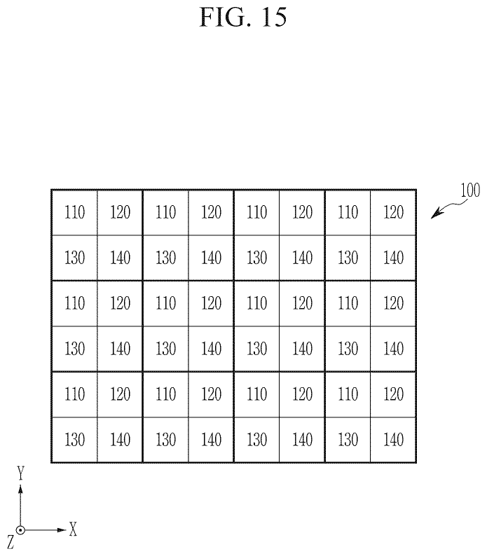

Referring to FIG. 2 and FIG. 3, the pixel array may include a sensor substrate 100, a color separation lens layer 200, and a spacer layer 300. The sensor substrate 100 may include a plurality of light-sensitive cells that sense light. The specific arrangement of the light-sensitive cells will be described later with reference to FIG. 15. In the image sensor of at least one example embodiment, each of the plurality of light-sensitive cells may be, for example, a photodiode (PD). However, the light-sensitive cells are not limited to photodiodes. The color separation lens layer 200 may be positioned on the spacer layer 300 and may include a plurality of nano posts NPs.

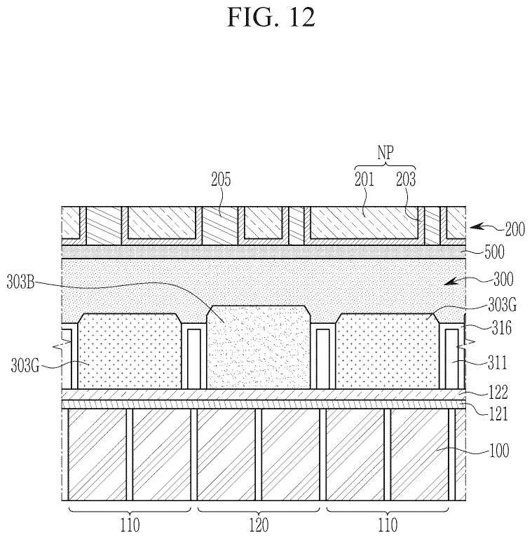

Although not shown in FIG. 2 and FIG. 3, the image sensor according to at least one example embodiment may further include a color filter positioned between the sensor substrate 100 and the spacer layer 300. However, according to at least one example embodiment, the color filter may be omitted. The specific structure will be described in detail later with reference to FIG. 12.

The color separation lens layer 200 is configured to split an incident light into incident light of different wavelength spectrums and onto at least two different light-sensitive cells of the sensor substrate 100. For this purpose, the size, position, arrangement, etc. of the nano post NP may be appropriately set in the color separation lens layer 200. The color separation lens layer 200 may have a plurality of regions each facing a plurality of light-sensitive cells of the sensor substrate 100. Additionally, according to an arrangement a relationship between each region and the plurality of nano posts NP, the incident light may have a predetermined phase distribution immediately after passing through the color separation lens layer 200.

The color separation lens layer 200 may include a nano post NP and a dielectric layer 205. The nano post NP may have a cylinder shape, as shown in FIG. 2 and FIG. 3. However, the shape of the nano post NP is not limited to the cylinder shape. For example, the nano post NP may be columnar a post, rectangular post, a pentagonal post, and/or the like. The nano posts NP may have various sizes and be spaced apart from each other on the upper surface of the spacer layer 300. The dielectric layer 205 may fill the space between the nano posts NP. The dielectric layer 205 may include a material with a lower refractive index than the material of the nano post NP. For example, the dielectric layer 205 may include SiO₂. However, the material of the dielectric layer 205 is not limited to SiO₂.

The nano post NP may include a first refraction layer 201 and a second refraction layer 203. The first refraction layer 201 may constitute the central body of the nano post NP and have a cylinder shape corresponding to the shape of the nano post NP. However, if the shape of the nano post NP is not cylindrical, the shape of the first refractive layer 201 may also not be cylindrical.

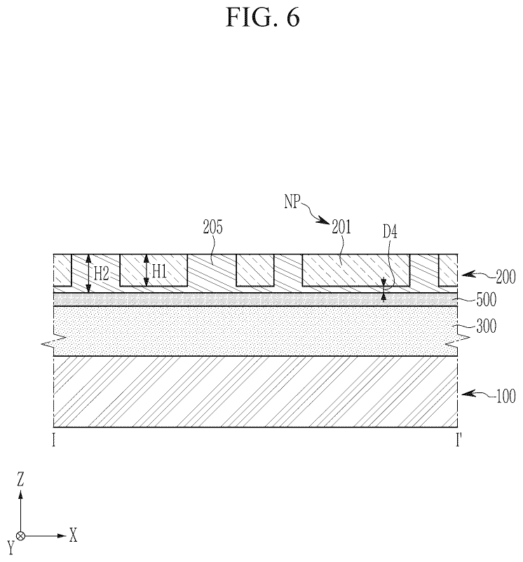

As illustrated in FIG. 3, the second refractive layer 203 may have a shape that surrounds the bottom surface and side surface of the first refractive layer 201. As will be explained separately later, the second refractive layer 203 and the dielectric layer 205 may include the same material. In this case, the boundary between the second refractive layer 203 and the dielectric layer 205 may be not distinguished and be recognized as one. That is, when the second refractive layer 203 and the dielectric layer 205 include the same material, the nano post NP may be recognized as including the second refractive layer 203, and may have the form in which the bottom surface and side surfaces of the first refractive layer 201 are surrounded by the dielectric layer 205. This is described separately in detail in FIG. 6 to FIG. 8.

In at least one example embodiment, the first refractive layer 201 may be formed of a material having a high refractive index. Additionally, in at least one example embodiment, the second refractive layer 203 may also be formed of a material having a high refractive index. In general, the relative refractive indexes may be defined based on the refractive index of SiO₂. That is, the first refraction layer 201 and/or the second refraction layer 203 may have a refractive index higher than SiO₂. In at least some example embodiments, the first refractive layer 201 and the second refractive layer 203 may be formed of a material having a higher refractive index than the material of the dielectric layer 205.

For example, the first refraction layer 201 may include one of SiN₃, Si₃N₄, ZnS, GaN, ZnSe, TiO₂, and amorphous silicon (a-Si: H) doped with hydrogen.

Additionally, the second refractive layer 203 may include a material having a lower refractive index than the first refractive layer 201. At this time, the refractive index of the second refractive layer 203 may be equal to or higher than the refractive index of the dielectric layer 205 and may have the lower refractive index than the first refractive layer 201. That is, the refractive index may be (in the order of lowest to highest) the dielectric layer 205, the second refractive layer 203, and the first refractive layer 201. For example, the second refraction layer 203 may include SiO₂ or Al₂O₃. However, these materials are only examples and the present disclosure is not limited thereto.

The thickness D1 of the second refraction layer 203 may be 5 nanometers (nm) to 30 nm. Also, the width D2 of the first refraction layer 201 may be 50 nm to 250 nm. In this specification, the width D2 of the first refractive layer 201 means the width of the widest part on a plane. That is, when the first refractive layer 201 has the cylindrical shape, the width D2 of the first refractive layer 201 is the diameter.

As will be explained separately later, the second refractive layer 203 may be formed by an atomic layer deposition (ALD) process. By forming the second refractive layer 203 in this way, the first refractive layer 201 having a fine width may be formed.

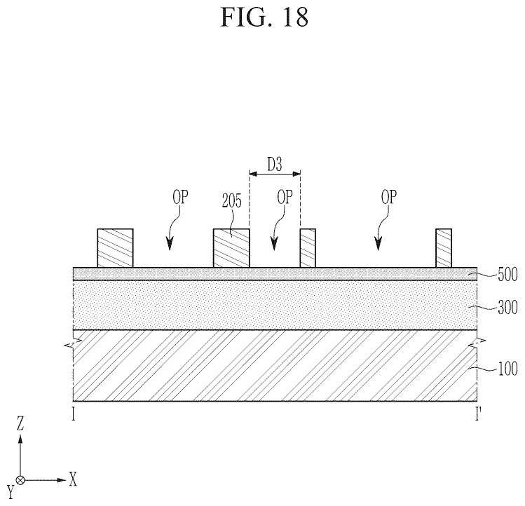

In order to form the nano post NP, a dielectric layer 205 may be first formed, and then the nano post NP may be formed through the patterning. At this time, as the resolution of the image sensor increases, the size of each pixel becomes smaller, and accordingly, the size of each nano post NP also needs to be formed smaller. However, the process of forming these fine patterns has some issues. For example, the formation of the nano posts NP is performed after the formation of the sensor substrate 100, and there is a limitation that a high-temperature process cannot be used during the formation process of the nano post NP. This is because using the high temperature process may cause a damage to the sensor substrate 100 that has already been formed. Thereby, the relatively high process temperatures of 250° C. or higher may not be used, and therefore there are restrictions when selecting a hard mask for forming the fine pattern. In contrast, according to at least one example embodiment, the second refractive layer 203 is formed using the ALD process after forming and patterning the dielectric layer 205. Accordingly, the width of the formed fine pattern is reduced by the thickness of the second refractive layer 203, and the first refractive layer 201 having the fine width may be formed. The specific effects are described in more detail in description of the manufacturing method of FIG. 18 to FIG. 21 below.

The spacer layer 300 is placed between the sensor substrate 100 and the color separation lens layer 200 and serves to maintain a constant interval between the sensor substrate 100 and the color separation lens layer 200. The spacer layer 300 may be formed of a material that is transparent to visible light, for example, a dielectric material having a lower refractive index than the nano post NP such as SiO2 or siloxane-based spin on glass (SOG), and having a low absorption rate in a visible light band. The thickness of the spacer layer 300 may be determined based on the focal length of the light collected by the color separation lens layer 200, and for example, may be selected within a range of about ½ to about 1.5 times the focal length of a light of a reference wavelength (λ0).

Referring to FIG. 3, an intermediate layer 500 may be positioned between the spacer layer 300 and the color separation lens layer 200. The intermediate layer 500 may function as an etch-stop layer. Therefore, as shown in FIG. 3, the nano post NP may be formed on top of the intermediate layer 500. The intermediate layer 500 may include Al₂O₃, but it is not limited thereto.

In at least one example embodiment, a portion of the intermediate layer 500 may be etched so that a portion of the nano post NP may be positioned within the intermediate layer 500. Additionally, in at least one example embodiment, the nano post NP may penetrate the intermediate layer 500 such that the bottom surface of the nano post NP may be positioned lower than the bottom surface of the intermediate layer 500.

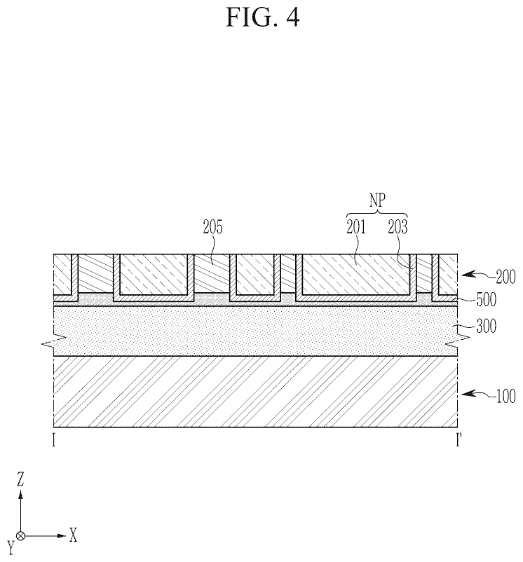

FIG. 4 is a view illustrating the same area as FIG. 3 for at least one example embodiment. Referring to FIG. 4, the description of the image sensor according to at least one example embodiment is the same as (or substantially similar to) the example embodiment of FIG. 3 except that the bottom surface of the nano post NP is located within the intermediate layer 500. Therefore, the repeat descriptions of the components are omitted. The structure illustrated in FIG. 4 may be formed by patterning a portion of the intermediate layer 500 together with the dielectric layer 205. That is, in the example embodiment of FIG. 4, the nano post NP may be positioned within the recess in which the intermediate layer 500 is partially etched. As shown in FIG. 4, the bottom surface of the second refractive layer 203 may be located within the intermediate layer 500, and a part of the side surface of the second refractive layer 203 may be in direct contact with the intermediate layer 500.

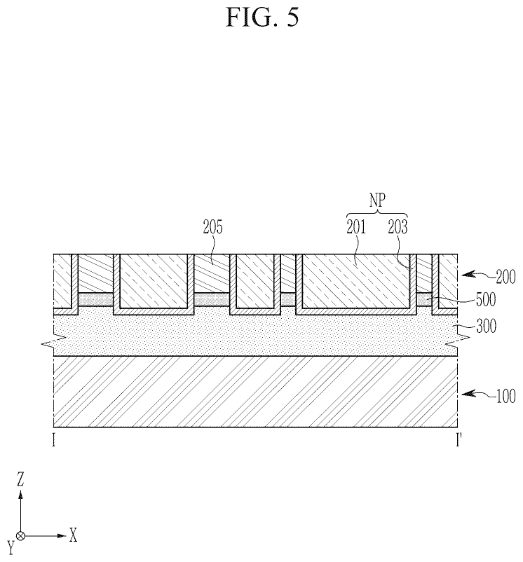

FIG. 5 is a view illustrating the same area as FIG. 3 for at least one example embodiment. Referring to FIG. 5, the image sensor according to at least one example embodiment may be the same as (or substantially similar to) the example embodiment of FIG. 3 except that the nano post NP penetrates the intermediate layer 500 and the bottom surface of the nano post NP is located lower than the bottom surface of the intermediate layer 500. Therefore, the repeat description of the components is omitted. In the example embodiment of FIG. 5, the bottom surface of the nano post NP may be located within the spacer layer 300. The structure like FIG. 5 may be formed by patterning a portion of the intermediate layer 500 and the spacer layer 300 together when patterning the dielectric layer 205. That is, as illustrated in FIG. 5, the nano post NP may be positioned to penetrate the intermediate layer 500, and the bottom surface of the second refractive layer 203 may be positioned within the spacer layer 300.

In FIGS. 3 to 5, the second refractive layer 203 and the dielectric layer 205 are depicted as being separated, but the second refractive layer 203 and the dielectric layer 205 may include the same material. In this case, the boundary between the second refractive layer 203 and the dielectric layer 205 may be indistinct and/or not recognized, such that the second refractive layer 203 and the dielectric layer may be recognized as one dielectric layer 205. FIG. 6 is a view illustrating the same area as FIG. 3 in at least one example embodiment in which the second refractive layer 203 and the dielectric layer 205 include the same material. Referring to FIG. 6, the image sensor according to at least one example embodiment is the same as (or substantially similar to) FIG. 3 except that the dielectric layer 205 is positioned in the area where the second refractive layer 203 was positioned. Therefore, the repeat description of the components is omitted. Referring to FIG. 6, the bottom surface and side surface of the first refractive layer 201 may be surrounded by the dielectric layer 205. Therefore, as illustrated in FIG. 6, the thickness H2 of the thickest portion of the dielectric layer 205 may be greater than the thickness H1 of the first refractive layer 201. Similarly, as illustrated in FIG. 6, the bottom surface of the dielectric layer 205 may be positioned lower than the bottom surface of the first refractive layer 201. As shown in FIG. 6, the thickness D4 of the dielectric layer 205 located on the bottom surface of the first refractive layer 201 can be 5 nm to 30 nm.

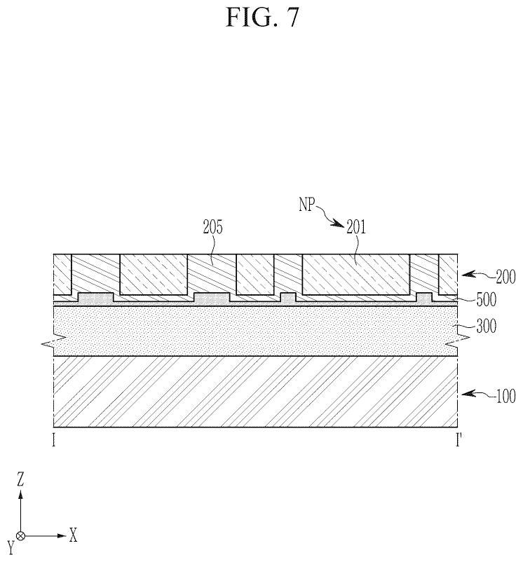

FIG. 7 is a view illustrating the same area as FIG. 4 in at least one example embodiment in which the second refractive layer 203 and the dielectric layer 205 include the same material. Referring to FIG. 7, the image sensor according to at least one example embodiment is the same as (or substantially similar to) FIG. 4 except that the dielectric layer 205 is positioned in the area where the second refractive layer 203 was positioned. Therefore, the repeat description of the components is omitted. Referring to FIG. 7, a portion of the dielectric layer 205 may be located within the intermediate layer 500.

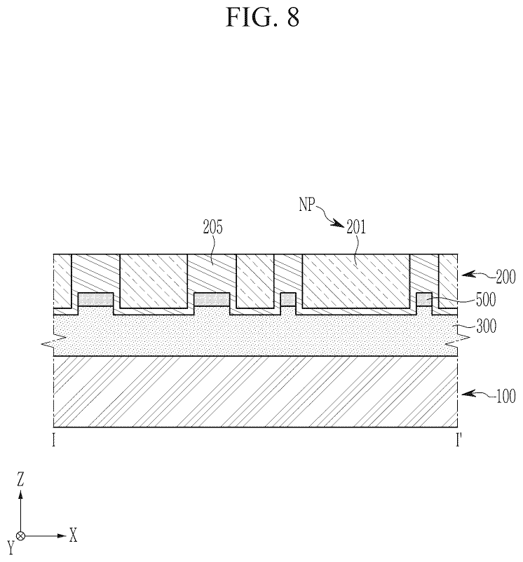

FIG. 8 is a view illustrating the same area as FIG. 5 in at least one example embodiment in which the second refractive layer 203 and the dielectric layer 205 include the same material. Referring to FIG. 8, the image sensor according to at least one example embodiment is the same as (or substantially similar to) FIG. 5 except that the dielectric layer 205 is positioned in the area where the second refractive layer 203 was positioned. Therefore, the repeat description of the components is omitted. Referring to FIG. 8, a portion of the dielectric layer 205 may be located within the spacer layer 300.

In FIG. 3 to FIG. 8, the configuration in which the color separation lens layer 200 is a single layer is illustrated, but in other embodiments, the color separation lens layer 200 may have a multilayer stacked structure.

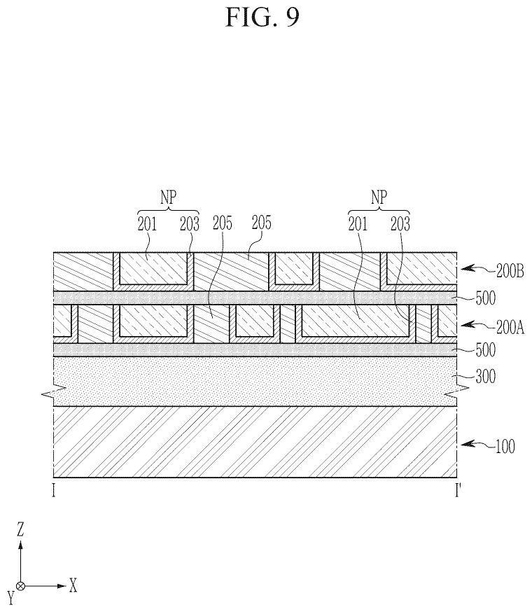

FIG. 9 is a view illustrating the same area as FIG. 3 for at least one example embodiment. Referring to FIG. 9, the color separation lens layer 200 may include a first color separation lens layer 200A and a second color separation lens layer 200B. The description of the stacked structure of the first color separation lens layer 200A and the second color separation lens layer 200B may each be the same as (or substantially similar to) the color separation lens layer 200 described above, so the repeat description of the components is omitted. The arrangement of the nano posts NP of the first color separation lens layer 200A and the arrangement of the nano posts NP of the second color separation lens layer 200B may be the same or different from each other. As illustrated in FIG. 9, some of the nano posts NP positioned in the first color separation lens layer 200A may overlap the nano posts NP positioned in the second color separation lens layer 200B. However, in at least one example embodiment, the nano post NP positioned in the first color separation lens layer 200A may not overlap the nano post NP positioned in the second color separation lens layer 200B.

In FIG. 9, the nano post NP positioned in the first color separation lens layer 200A includes a first refractive layer 201 and a second refractive layer 203, and the refractive index of the first refractive layer 201 may be higher than the refractive index of the second refractive layer 203. Additionally, the nano post NP positioned in the second color separation lens layer 200B may include a first refractive layer 201 and a second refractive layer 203, and the refractive index of the first refractive layer 201 may be higher than the refractive index of the second refractive layer 203. However, this is just an example, and the refractive indices of the nano posts NP located in the first color separation lens layer 200A and the nano posts NP located in the second color separation lens layer 200B may be different. That is, the nano post NP positioned in the first color separation lens layer 200A may have the refractive index of the first refractive layer 201 greater than the refractive index of the second refractive layer 203, and the nano post NP positioned in the second color separation lens layer 200B may have the refractive index of the first refractive layer 201 less than the refractive index of the second refractive layer 203. Conversely, the nano post NP positioned in the first color separation lens layer 200A may have the refractive index of the first refractive layer 201 lower than the refractive index of the second refractive layer 203, and the nano post NP positioned in the second color separation lens layer 200B may have the refractive index of the first refractive layer 201 higher than the refractive index of the second refractive layer 203. That is, according to at least one example embodiment, the shape and refractive index of the nano post included in each color separation lens layer may be different. In at least one example embodiment, the critical dimension (CD) between nano posts NP in the first color separation lens layer 200A

In addition, FIG. 9 illustrates the configuration in which the nano post NP positioned in the first color separation lens layer 200A includes the first refractive layer 201 and the second refractive layer 203, and the nano post NP positioned in the second color separation lens layer 200B includes the first refractive layer 201 and the second refractive layer 203, but the shape of the nano post may be different in each color separation lens layer.

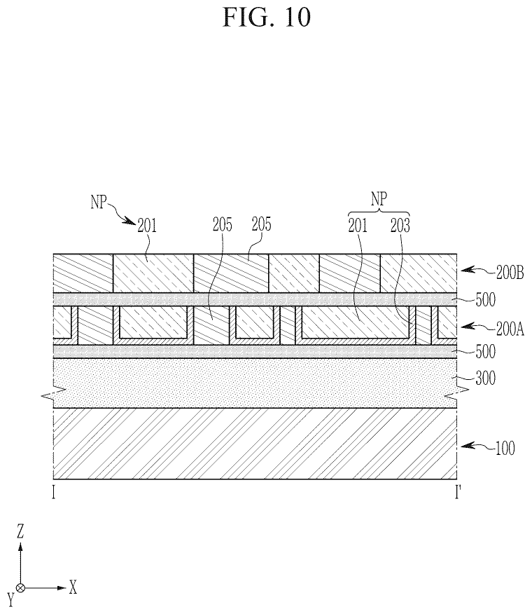

FIG. 10 is a view illustrating the same area as FIG. 9 for at least one example embodiment. Referring to FIG. 10, the image sensor according to at least one example embodiment is the same as (or substantially similar to) the embodiment of FIG. 9, except that the nano post NP positioned in the first color separation lens layer 200A includes the first refractive layer 201 and the second refractive layer 203, and the nano post NP positioned in the second color separation lens layer 200B includes the first refractive layer 201. Therefore, the repeat description of the components is omitted.

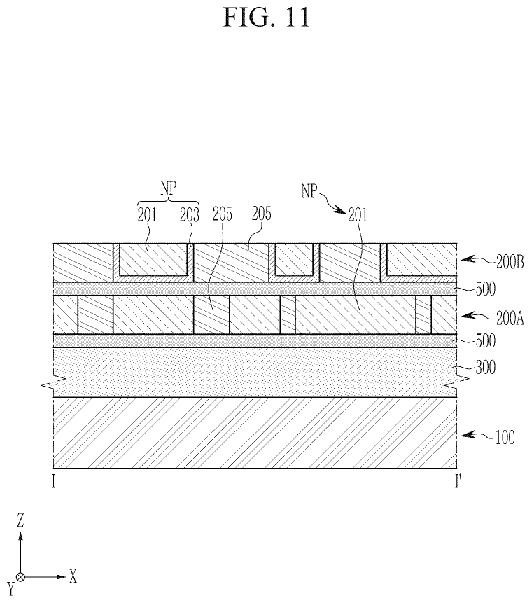

FIG. 11 is a view illustrating the same area as FIG. 10 for at least one example embodiment. Referring to FIG. 11, the image sensor according to at least one example embodiment is the same as (or substantially similar to) the embodiment of FIG. 10, except that the nano post NP positioned in the first color separation lens layer 200A includes the first refractive layer 201, and the nano post NP positioned in the second color separation lens layer 200B includes the first refractive layer 201 and the second refractive layer 203. Repeat descriptions of components are omitted.

Although some examples have been described above, the shapes of the first color separation lens layer (200A) and the second color separation lens layer (200B) may vary. In addition, at least one example embodiment in which the color separation lens layer includes a first color separation lens layer (200A) and a second color separation lens layer (200B) has been described, but this is only an example, and the color separation lens layer may be formed by stacking three or more color separation lens layers.

Above, for convenience of explanation, the structure of the image sensor is briefly described. Below, the structure of the image sensor is described in more detail with reference to FIG. 12. FIG. 12 is a cross-sectional diagram schematically illustrating the structure of an image sensor.

Referring to FIG. 12, the image sensor may include a sensor substrate 100 including a plurality of first light-sensing cells 110 that detect light of a first wavelength and a plurality of second light-sensing cells 120 that detect light of a second wavelength different from the first wavelength. For example, in at least one example embodiment, the first wavelength may be a region of a green light within a visible light wavelength band and the second wavelength may be in a blue region of the visible light wavelength band. In this drawing, the third sensing cell and the fourth sensing cell are not depicted, but when viewed from a cross-sectional view in another horizontal direction, the third sensing cell and the fourth sensing cell may be depicted. The configuration of the sensor substrate 100 including the third detection cell and the fourth detection cell is described in detail later in FIG. 15.

The image sensor according to at least one example embodiment may include at least two or more lower anti-reflection layers arranged on the upper surface of the sensor substrate 100. In FIG. 12, the lower anti-reflection layer is illustrated as including a first lower anti-reflection layer 121 and a second lower anti-reflection layer 122. However, the lower anti-reflection layer is not limited thereto and may include three, four or more lower anti-reflection layers. The lower anti-reflection layer may improve a light utilization efficiency by reducing the amount of light reflected from the upper surface of the sensor substrate 100 (e.g., from the incident light). In other words, the lower anti-reflection layer helps light incident from the outside to be detected by the sensor substrate 100. Each of the first lower anti-reflection layer 121 and the second lower anti-reflection layer 122 may be formed to a thickness of 80 nanometers (nm) to 120 nm.

The image sensor may be disposed on the sensor substrate 100 and may include a first color filter 303G disposed on the first light-sensing cell 110 and a second color filter 303B disposed on the second light-sensing cell 120. For example, the first color filter 303G and the fourth color filter may be green color filters that transmit only green light, and the second color filter 303B may be a blue color filter that transmits only blue light. Although not shown, the image sensor may further include a third color filter disposed over the third pixel and a fourth color filter disposed over the fourth pixel. The third color filter may be, for example, a red color filter that transmits only red light.

As the nano post NP is configured as not only a simple light collector but also a color separator, light that has already been color separated to a considerable extent may proceed toward the first to fourth sensing cells, so a light loss may be reduced even if the color filter is used. Using the color filter may further improve the color purity of the image sensor. However, the example embodiments are not limited thereto, and if the color separation efficiency of the nano post NP is sufficiently high (e.g., 80% or more, 90% or more, 99% or more, and/or 99.9% or more), the color filter may be omitted.

The image sensor according to at least one example embodiment may provide the sufficient amount of light to the pixels even if the pixel size is reduced because there is almost no light loss due to the color filter, for example, an organic color filter. Therefore, it is possible to manufacture an ultra-high-resolution, ultra-small, high-sensitivity image sensor with hundreds of millions of pixels. These ultra-high-resolution, ultra-small, high-sensitivity image sensor may be employed in various high-performance optical devices or high-performance electronic devices. Such electronic devices may be smart phones, mobile phones, cell phones, personal digital assistants (PDAs), laptops, PCs, various portable devices, home appliances, security cameras, medical cameras, automobiles, Internet of Things (IoT) devices, and other mobile or non-mobile computing devices, but are not limited thereto.

Referring to FIG. 12, the image sensor according to at least one example embodiment may include a Bayer pattern (311) and a protective film (316) placed between color filters. The bayer pattern 311 may be positioned between the adjacent color filters 303 to separate the adjacent color filters 303 from each other. For example, the bayer pattern 311 may have a lattice structure. The bayer pattern 311 may include a material having a lower refractive index than the color filter 303. The Bayer pattern 311 may include an organic material. For example, the Bayer pattern 311 may be a polymer layer including silica nanoparticles. The Bayer pattern 311 has the low refractive index, which may increase the amount of light incident on the sensor substrate 100 and reduce a crosstalk between neighboring sensing cells. The protective film 316 may cover the surface of the Bayer pattern 311 with a substantially uniform thickness. The protective film 316 may include, for example, a single film or multiple films of at least one of an aluminum oxide film and a silicon carbide oxide film. The protective film 316 may protect the color filter 303 from, e.g., moisture. For example, the protective film 316 may have a moisture absorption function.

As illustrated in FIG. 12, the Bayer pattern 311 may be located between the color filters and may not overlap the lower surface of the color filter. The protective film 316 may be also positioned to cover the Bayer pattern 311 and may not overlap the lower surface of the color filter.

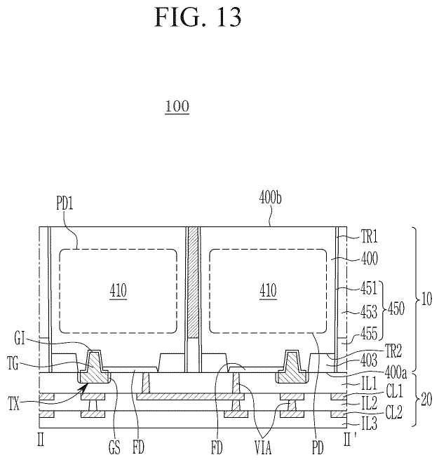

The descriptions of the spacer layer 300 and the color separation lens layer 200 are the same as those described above and are therefore omitted. Then, the structure of the sensor substrate 100 will be described in more detail below with reference to FIG. 13. However, the structure of the sensor substrate 100 described below is only an example and the present disclosure is not limited thereto. FIG. 13 is a view illustrating a part of a cross-section of a sensor substrate (100).

Referring to FIG. 13, the sensor substrate 100 may include a photoelectric conversion layer 10 and a first wiring region 20. The photoelectric conversion layer 10 may include a first substrate 400 and a PD isolation pattern 450.

Referring to FIG. 13, the first substrate 400 may include a first surface 400a and a second surface 400b facing each other. Light may be incident on the second surface 400b of the first substrate 400. The first wiring region 20 may be located on the first surface 400a of the first substrate 400. The spacer layer 300 and the color separation lens layer 200 described above may be positioned on the second surface 400b of the first substrate 400.

The first substrate 400 may be a semiconductor substrate or a silicon on insulator (SOI) substrate. For example, the semiconductor substrate may include, for example, a silicon substrate, a germanium substrate, or a silicon-germanium substrate. The first substrate (400) may include a first challenge type impurity. For example, the first challenge type impurity may be a p-type impurity such as aluminum (Al), boron (B), indium (In), and/or gallium (Ga).

The photoelectric element conversion region 410 may be a region doped with a second conductive type impurity within the first substrate 400. The second challenge type impurity may have a challenge type opposite to that of the first challenge type impurity. The second challenge type impurities may include n-type impurities such as phosphorus, arsenic, bismuth, and/or antimony. For example, each photoelectric element conversion region 410 may include a first region adjacent to the first surface 400a and a second region adjacent to the second surface 400b. There may be a difference in impurity concentration between the first region and the second region of the photoelectric element conversion region 410. Therefore, the photoelectric element conversion region 410 may have a potential gradient between the first surface 400a and the second surface 400b of the first substrate 400. As another example, the photoelectric element conversion region 410 may not have a potential gradient between the first surface 400a and the second surface 400b of the first substrate 400.

The first substrate 400 and the photoelectric element conversion region 410 may form a photoelectric conversion element PD1. The photoelectric conversion element PD1 may be a photodiode. That is, a photodiode may be formed by a p-n junction between the first substrate 400 of a first conductive type and the photoelectric conversion element region (410) of a second conductive type. The photoelectric element conversion region 410 constituting the photodiode may generate and accumulate photocharges in proportion to the intensity of the incident light.

A transmission transistor TX may be positioned on the first surface 400a of the first substrate 400. The transmission transistor TX may be electrically connected to the photoelectric element conversion region 410. The transmission transistor TX may include a transmission gate TG and a floating diffusion region FD.

A gate dielectric layer GI may be positioned between the transmission gate TG and the first substrate 400. A gate spacer GS may be positioned on the side wall of the transmission gate TG. The gate spacer GS, for example, may include silicon nitride, silicon carbonization nitride or silicon oxidation nitride.

The floating diffusion region FD may be adjacent to one side of the transmission gate TG. The floating diffusion region FD may have a second conductivity type (e.g., an n-type) opposite to the first substrate 400. Although not shown in FIG. 12, other transistors may be positioned on the first substrate 400 in addition to the transmission transistor TX.

Referring to FIG. 13, the PD isolation pattern 450 may be positioned within the first trench TR1. The first trench TR1 may be recessed from the first surface 400a of the first substrate 400. The PD isolation pattern 450 may extend toward the second surface 400b from the first surface 400a of the first substrate 400. The PD isolation pattern 450 may be a deep trench isolation (DTI) layer. The PD isolation pattern 450 may penetrate the first substrate 400. The vertical height of the PD isolation pattern 450 may be substantially the same as the vertical thickness of the first substrate 400. For example, the width of the pixel separation pattern 450 may gradually decrease from the first surface 400a of the first substrate 400 toward the second surface 400b.

The PD isolation pattern 450 may include a first isolation pattern 451, a second isolation pattern 453 and a capping pattern 455. The first isolation pattern 451 may be positioned along the side wall of the first trench TR1. The first isolation pattern 451, for example, may include a silicon-based insulating material (e.g., silicon nitride, silicon oxide or silicon oxidation nitride) and/or a high dielectric material (e.g., hafnium oxide or aluminum oxide). As another example, the first isolation pattern 451 may include a plurality of layers, and each of the layers may include a different material. The first isolation pattern 451 may have the refractive index lower than the first substrate 400. Accordingly, the crosstalk phenomenon between the pixels PX located on the first substrate 400 may be protected against (e.g., prevented and/or reduced).

The second isolation pattern 453 may be positioned within the first isolation pattern 451. For example, the side wall of the second isolation pattern 453 may be surrounded by the first isolation pattern 451. The first isolation pattern 451 may be positioned between the second isolation pattern 453 and the first substrate 400. The second isolation pattern 453 may be spaced from the first substrate 400 by the first isolation pattern 451. Accordingly, when the image sensor operates, the second isolation pattern 453 may be electrically separated from the first substrate 400. The second isolation pattern 453 may include a crystalline semiconductor material, for example, a polycrystalline silicon. For example, the second isolation pattern 453 may further include a dopant, and the dopant may include a first conductivity type impurity or a second conductivity type impurity.

For example, the second isolation pattern 453 may include a doped polycrystalline silicon. Also, the second isolation pattern 453 may include an undoped crystalline semiconductor material. For example, the second isolation pattern 453 may include an undoped polycrystalline silicon. The term “undoped” may mean that no intentional doping process has been performed. Thereby, trace amounts of dopants may be present, but may be at such concentrations too low to detect and/or to have a measurable effect. The dopant may include an n-type dopant and a p-type dopant.

The capping pattern 455 may be positioned on the lower surface of the second isolation pattern 453. The capping pattern 455 may be disposed adjacent to the first surface 400a of the first substrate 400. The capping pattern 455 may include a non-conductive material. For example, the capping pattern 455 may include a silicon-based insulating material (e.g., silicon nitride, silicon oxide or silicon oxidation nitride) or a high dielectric material (e.g., hafnium oxide or aluminum oxide). Accordingly, the pixel separation pattern 450 may protect against (e.g., prevent and/or reduce) photocharges generated by the incident light incident on the pixel PX from being incident on other adjacent pixels PX due to a random drift. That is, the PD isolation pattern 450 may protect against (e.g., prevent and/or reduce) a crosstalk between the pixels PX.

An element isolation pattern 403 may be positioned within the first substrate 400. For example, the element isolation pattern 403 may be positioned within the second trench TR2. The second trench TR2 may be recessed from the first surface 400a of the first substrate 400. The element isolation pattern 403 may be a shallow trench isolation (STI). The element isolation pattern 403 may define an active pattern. The upper surface of the element isolation pattern 403 may be positioned within the first substrate 400. The width of the element isolation pattern 403 may gradually decrease from the first surface 400a of the first substrate 400 to the second surface 400b. The upper surface of the element isolation pattern 403 may be vertically separated from the photoelectric element conversion region 410. The element isolation pattern 403 may include the same material as the first isolation pattern 451 of the PD isolation pattern 450, in this case, the boundary of the element isolation pattern 403 and the first isolation pattern 451 may be not recognized. However, it is only one example, and the present disclosure is not limited thereto.

In FIG. 13, it is described that the element isolation pattern 403, the PD isolation pattern 450 and the first surface 400a of the first substrate 400 are positioned on the same plane, but it is only one example, and the present disclosure is not limited thereto. For example, the element isolation pattern 403, the PD isolation pattern 450 and the first surface 400a of the first substrate 400 may not form a coplanar. The element isolation pattern 403 and the PD isolation pattern 450 may be positioned to be protruded or recessed from the first surface 400a of the first substrate 400. In at least one example embodiment, the element isolation pattern 403 and the capping pattern 455 may be collectively referred to as a shallow trench isolation pattern.

In addition, the upper surface of the element separation pattern 403 and the upper surface of the pixel separation pattern 450 are depicted to be parallel, but this is only an example, and the upper surface of the element separation pattern 403 and the upper surface of the pixel separation pattern 450 may include a curved surface.

The first wiring region 20 may be positioned on the first surface 400a of the first substrate 400 and include a plurality of insulation layers IL1, IL2, and IL3, a plurality of wiring layers CL1 and CL2, and a via.

The insulation layer may include a first insulation layer IL1, a second insulation layer IL2 and a third insulation layer IL3.

The first insulation layer IL1 may cover the first surface 400a of the first substrate 400. The first insulation layer IL1 may cover the gate electrode TG. The second insulation layer IL2 may be positioned on the first insulation layer IL1. The third insulation layer IL3 may be positioned on the second insulation layer IL2.

The first insulation layer to third insulation layers IL1, IL2, and IL3 may include non-conductive materials (e.g., electrically insulating materials). For example, the first insulation layer to third insulation layers IL1, IL2, and IL3 may include a silicon-based insulating material such as silicon oxide, silicon nitride or silicon oxidation nitride.

The first wiring region 20 may include a first wiring layer CL1 and a second wiring layer CL2. The first wiring layer CL1 may be positioned within the second insulation layer IL2. The second wiring layer CL2 may be positioned within the third insulation layer IL3.

A plurality of vias VIA may be positioned in the first insulation layer IL1, the second insulation layer IL2, and the third insulation layer IL3. The via VIA may connect the floating diffusion region FD, the first wiring layer CL1 and the second wiring layer CL2 to each other.

The first wiring layer CL1, the second wiring layer CL2 and the via VIA may include electrically conductive materials, such as metallic materials. For example, the first wiring layer CL1, the second wiring layer CL2 and the via VIA may include copper (Cu).

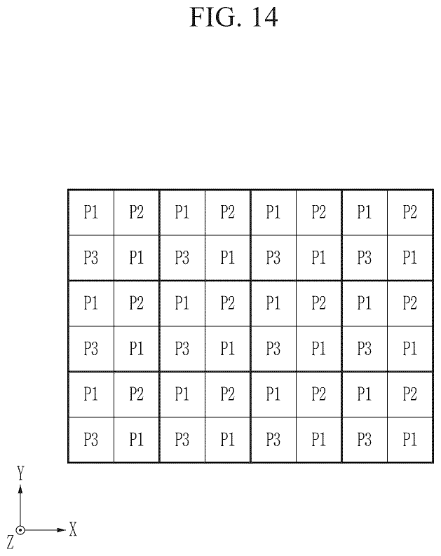

Then, the components of the pixel array are described in more detail with reference to FIG. 14 to FIG. 17 below.

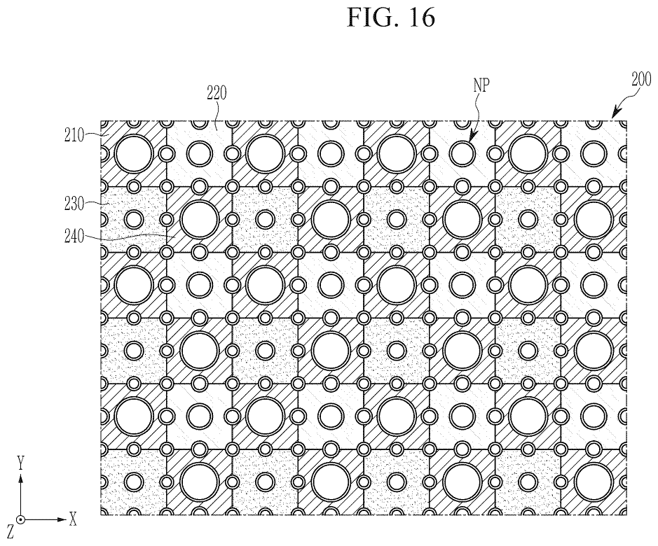

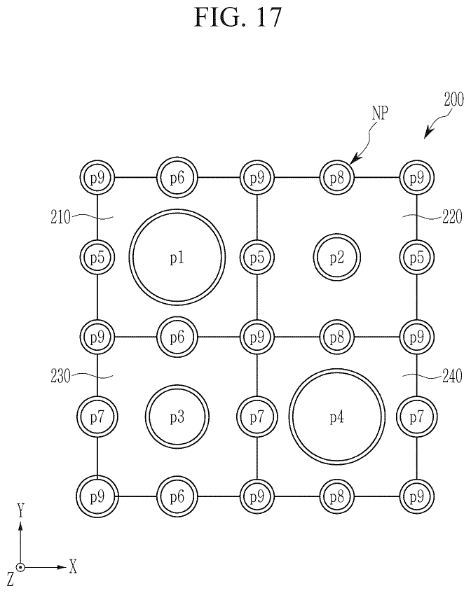

FIG. 14 and FIG. 15 are plan views showing an arrangement of pixels and an arrangement of light-sensitive cells corresponding to pixel regions in an image sensor according to at least one example embodiment. FIG. 16 is a top plan view showing an arrangement of nano posts in a color separation lens layer of an image sensor according to at least one example embodiment. FIG. 17 is an enlarged top plan view showing a partial region of FIG. 16.

Referring to FIG. 14 to FIG. 17, and FIG. 3, the pixel array may include a sensor substrate 100 and a color separation lens layer 200.

The sensor substrate 100 may include a plurality light-sensitive cells 110 and 120 sensing light. The sensor substrate 100 may further include light-sensitive cells 130 and 140 sensing light. The color separation lens layer 200 may be placed at a predetermined distance above the sensor substrate 100.

The sensor substrate 100 may include a first light-sensitive cell 110, a second light-sensitive cell 120, a third light-sensitive cell 130 and a fourth light-sensitive cell 140 configured to convert light into an electric signal. The first light-sensitive cell 110 and the second light-sensitive cell 120 may be alternately disposed along the first direction (the direction X), as shown in FIG. 15. Also, the third light-sensitive cell 130 and the fourth light-sensitive cell 140 may be also alternately disposed along the first direction (the direction X). Meanwhile, the first light detection cell 110 and the third light detection cell 130 may be arranged alternately along the second direction (a direction Y), and the second light detection cell 120 and the fourth light detection cell 140 may be also arranged alternately along the second direction (the direction Y). This area division may be intended to sense the incident light to be divided into a pixel unit.

For example, the first light-sensing cell 110 and the fourth light-sensing cell 140 may sense light of a first spectrum corresponding to the first pixel P1, the second light-sensing cell 120 may sense light of a second spectrum corresponding to the second pixel P2, and the third light-sensing cell 130 may sense light of a third spectrum corresponding to the third pixel P3. For example, light in the first spectrum may be a green light, light in the second spectrum may be a blue light, and light in the third spectrum may be a red light. However, the example embodiments are not limited thereto.

The color separation lens layer 200 may include a plurality of nano posts NP arranged according to predetermined rules. Here, the rules may be applied to parameters such as a shape, a size (a width, a height), a spacing, and an array form of the nano posts (NP). These parameters may be determined according to a target phase distribution that the color separation lens layer 200 intends to be implemented for the incident light. The target phase distribution may refer to a phase distribution at a position immediately after the incident light passes through the color separation lens layer 200. However, the nano posts NP may be arranged irregularly. The description of the nano posts NP is the same as described above. Therefore, the repeat description of the components is omitted.

The nano posts NP may have a geometric dimension of a sub-wavelength. The sub-wavelength may mean a length smaller than the wavelength of the incident light (e.g., the light for which the desired phase distribution is desired to be formed). That is, at least one of the dimensions defining the shape of the nano post NP may be the sub-wavelength. For example, in the image sensor 1000 of at least one example embodiment, the nano post NP may have the cylindrical shape, and the height and diameter of the cylinder may be about 200 nm. However, the dimensions of the nano posts NP are not limited thereto.

As illustrated in FIG. 2, the nano post NP may be supported by a spacer layer 300 interposed between it and the sensor substrate 100. A repeat description of the spacer layer 300 is omitted.

The nano posts NP that have the difference in the refractive index from the surrounding materials may change the phase of light passing through the nano post NP. This may be due to the phase delay caused by the geometric dimension of the sub-wavelength of the nano post NP. The degree of the phase delay may be determined by the detailed shape dimensions, the array configuration, etc. of the nano posts NP. The color separation lens layer 200 may implement the required phase distribution for the incident light by appropriately setting the degree of the phase delay occurring in each of the plurality of nano posts NP.

That is, the shape, size, and arrangement of the plurality of nano posts NP may be determined to form the appropriate phase distribution. Through this phase distribution formation, the plurality of nano posts NP may focus light of the different spectra onto the first light-sensing cells 110 and the second light-sensing cells 120 adjacent to each other. In addition, through this phase distribution formation, the plurality of nano posts NP may focus light of the different spectra onto the third light-sensing cells 130 and the fourth light-sensing cells 140 adjacent to each other.

As shown in FIG. 15 and FIG. 16, the color separation lens layer 200 may be classified into a plurality of regions 210, 220, 230, and 240 that correspond one-to-one with and face the plurality of light-sensing cells 110, 120, 130, and 140. In each of plurality of regions 210, 220, 230, and 240, one or more nano posts NP may be placed. The nano posts NP may vary in at least one of the shape, size, and arrangement depending on the region.

The first region 210 and the first light-sensing cell 110 may be arranged to correspond to each other, and the second region 220 and the second light-sensing cell 120 may be arranged to correspond to each other. Additionally, the third region 230 and the third light-sensing cell 130 may be arranged to correspond to each other, and the fourth region 240 and the fourth light-sensing cell 140 may be arranged to correspond to each other.

The color separation lens layer 200 may include a plurality of unit pattern arrays arranged two-dimensionally. Each unit pattern array may include four regions arranged in a 2×2 configuration, for example the first region 210, the second region 220, the third region 230, and the fourth region 240.

In FIG. 15 and FIG. 16, the plurality of regions 210, 220, 230, and 240 and the plurality of light-sensing cells 110, 120, 130, and 140 are depicted as having the same size and facing each other in the vertical direction. However, this is an example and is not limited to this structure. For example, the plurality of regions defined in the different shapes may correspond to the plurality of light-sensitive cells. This also equally applies to other embodiments below.

The color separation lens layer 200 may be divided into regions such that light of the first spectrum is branched and focused on the first light detection cell 110 and the fourth light detection cell 140, light of the second spectrum is branched and focused on the second light detection cell 120, and light of the third spectrum is branched and focused on the third light detection cell 130. Additionally, for this purpose, the size, shape, and arrangement of nano posts NP may be determined for each region.

As illustrated in FIG. 14, the pixel arrangement of the pixel array may be an arrangement similar to a Bayer pattern. The single unit pixel may include four quadrant regions. For example, the quadrant region may be assigned to two first pixels P1, one second pixel P2, and one third pixel P3. These unit pixels may be two-dimensionally repeated along the first direction (the direction X) and the second direction (the direction Y).

Within the unit pixel in the form of the 2×2 array, two first pixels P1 may be arranged in one diagonal direction, and one second pixel P2 and one third pixel P3 may be arranged in the other diagonal direction. Referring to the overall pixel arrangement, a first row in which the first pixel P1 and the second pixel P2 are arranged alternately along the first direction (the direction X), and a second row in which the third pixel P3 and the first pixel P1 are arranged alternately along the first direction (the direction X) may be repeatedly arranged along the second direction (the direction Y).

The colors of the first pixel P1, the second pixel P2, and the third pixel P3 may not be fixed to a single color. The color or wavelength distribution of the first pixel P1, the second pixel P2, and the third pixel P3 may be expressed as the first spectrum, the second spectrum, and the third spectrum, respectively.

Referring to FIG. 15, the plurality of first light-sensing cells 110, second light-sensing cells 120, and third light-sensing cells 130 may be two-dimensionally arranged along the first direction (the direction X) and the second direction (the direction Y) such that rows in which first light-sensing cells 110 and second light-sensing cells 120 are alternately arranged and rows in which the third light-sensing cells 130 and the fourth light-sensing cells 140 are alternately arranged are alternately repeated. Accordingly, the first light-sensing cell 110 or the fourth light-sensing cell 140 may correspond to the first pixel P1, the second light-sensing cell 120 may correspond to the second pixel P2, and the third light-sensing cell 130 may correspond to a third pixel P3.

Referring to FIG. 14 to FIG. 16 together, the first light-sensing cell 110 and the first region 210 may correspond to the first pixel P1, and the fourth light-sensing cell 140 and the fourth region 240 may correspond to another first pixel P1. Additionally, the second light-sensing cell 120 and the second region 220 may correspond to the second pixel P2, and the third light-sensing cell 130 and the third region 230 may correspond to the third pixel P3.

In addition, as illustrated in FIG. 16, nano posts (NP) having different cross-sectional areas are arranged at the center of the first pixel P1), the second pixel P2), and the third pixel P3), and nano posts (NP) may also be arranged at the center of the boundary between pixels and at the intersection of the boundary lines between pixels. The cross-sectional area of the nano post NP placed at the boundary between the pixels may be smaller than that of the nano post NP placed at the center of the pixel.

FIG. 17 illustrates in detail the arrangement of the nano posts NP in some areas of FIG. 16, e.g., the first to fourth region 210, 220, 230, and 240 constituting the unit pattern array. That is, in FIG. 17, the nano posts NP are indicated as p1 to p9 according to their detailed positions within the unit pattern array.

Referring to FIG. 17 for more detailed explanation, among the nano posts NP, the cross-sectional area of the nano post p1 arranged in the center of the first region 210 and the nano post p4 arranged in the center of the fourth region 240 may be larger than the cross-sectional area of the nano post p2 arranged in the center of the second region 220 or the nano post p3 arranged in the center of the third region 230. Additionally, the cross-sectional area of the nano post p2 arranged at the center of the second region 220 may be larger than the cross-sectional area of the nano post p3 arranged at the center of the third region 230. However, this is only one example, and the nano posts NP of various shapes, sizes, and arrangements may be applied as needed. Here, the cross-sectional area may mean the area of the cross-section perpendicular to the third direction (a direction Z) of the nano post NP.

The nano posts NP provided in the first and fourth regions 210 and 240 may have different distribution rules along the first direction (the direction X) and the second direction (the direction Y). For example, the nano posts NP arranged in the first and fourth regions 210 and 240 may have the different size arrangements along the first direction (the direction X) and the second direction (the direction Y). That is, as illustrated in FIG. 17, among the nano posts (NP), the cross-sectional area of the nano post p5 located at the boundary between the first region 210 and the second region 220 adjacent in the first direction (the direction X) and the cross-sectional area of the nano post p6 located at the boundary between it and the third region 230 adjacent in the second direction (the direction Y) may be different from each other. Similarly, the cross-sectional area of the nano post p7 located at the boundary between the fourth region 240 and the third region 230 adjacent in the first direction (the direction X) and the cross-sectional area of the nano post p8 located at the boundary between it and the second region 220 adjacent in the second direction (the direction Y) may be different from each other.

On the other hand, the nano posts NP arranged in the second region 220 corresponding to the second pixel P2 and the third region 230 corresponding to the third pixel P3 may have symmetrical distribution rules along the first direction (the direction X) and the second direction (the direction Y). That is, as illustrated in FIG. 17, among the nano posts NP, the cross-sectional areas of the nano post p5 located at the boundary between the adjacent pixels in the first direction (the direction X) in the second region 220 and the nano post p8 located at the boundary between the adjacent pixels in the second direction (the direction Y) may be equal to each other, and in the third region 230, the cross-sectional areas of the nano post p7 located at the boundary between the adjacent pixels in the first direction (the direction X) and the nano post p6 located at the boundary between the adjacent pixels in the second direction (the direction Y) may be substantially equal to each other.

Meanwhile, the nano posts p9 arranged at four corners of each of the first region 210, the second region 220, the third region 230, and the fourth region 240, e.g., at the positions where four regions intersect, may all have the same or a substantially similar cross-sectional area. This distribution may be attributed to the pixel arrangement similar to the Bayer pattern. While the second pixel P2 and the third pixel P3 have the same pixels adjacent in the first direction (the direction X) and the second direction (the direction Y) as the first pixel P1, the first pixel P1 corresponding to the first region 210 may be different from each other in that the pixel adjacent in the first direction (the direction X) is the second pixel P2 and the pixel adjacent in the second direction (the direction Y) is the third pixel P3, and the first pixel P1 corresponding to the fourth region 240 may be different from each other in that the pixel adjacent in the first direction (the direction X) is the third pixel P3 and the pixel adjacent in the second direction (the direction Y) is the second pixel P2. In addition, the first pixel P1 corresponding to the first region 210 and the fourth region 240 may have the same pixels adjacent to each other in four diagonal directions as the first pixel P1, the second pixel P2 corresponding to the second region 220 may have the same pixels adjacent to each other in four diagonal directions as the third pixel P3, and the third pixel P3 corresponding to the third region 230 may have the same pixels adjacent to each other in four diagonal directions as the second pixel P2.

Accordingly, in the second region 220 and the third region 230 corresponding to the second pixel P2 and the third pixel P3, respectively, the nano posts NP may be arranged in a form of a 4-fold symmetry, and in the first and fourth regions 210 and 240 corresponding to the first pixel P1, the nano posts NP may be arranged in a form of a 2-fold symmetry. In particular, the first region 210 and the fourth region 240 may be rotated 90° relative to each other.

The plurality of nano posts NP are depicted as having a symmetrical circular cross-sectional shape, but are not limited thereto. For example, some nano posts NP that have a cross-sectional shape with an asymmetrical shape may be included. Specifically, in the first region 210 and the fourth region 240 corresponding to the first pixel P1, the nano posts NP having an asymmetrical cross-sectional shape in which the widths in the first direction (the direction X) and the second direction (the direction Y) are different may be employed, and in the second region 220 and the third region 230 corresponding to the second pixel P2 and the third pixel P3, respectively, the nano posts NP having a symmetrical cross-sectional shape in which the widths in the first direction (the direction X) and the second direction (the direction Y) are the same may be employed.

However, the shape and arrangement of these nano posts NP are examples, and the present disclosure is not limited thereto. The nano posts NP may be arranged irregularly.

The arrangement rule of the illustrated color separation lens layer 200 may be an example of implementing the target phase distribution that causes light of the first spectrum to be split and focused on the first light detection cell 110 and the fourth light detection cell 140, light of the second spectrum to be split and focused on the second light detection cell 120, and light of the third spectrum to be split and focused on the third light detection cell 130 at the position immediately after passing through the color separation lens layer 200. However, the arrangement rule of the color separation lens layer 200 is not limited to the illustrated pattern.

The shape, size, and arrangement of the nano posts NP provided in each region of the color separation lens layer 200 may be determined so that the phase in which light of the first wavelength is focused onto the first light detection cell 110 and the fourth light detection cell 140 is formed at the location passing through the color separation lens layer 200, and a phase which it does not proceed to the adjacent second light detection cell 120 and third light detection cell 130 is formed.

Likewise, the shape, size, and arrangement of the nano posts NP provided in each region of the color separation lens layer 200 may be determined so as to form a phase in which light of the second wavelength is focused onto the second light-sensing cell 120 at the location where it has passed through the color separation lens layer 200 and does not proceed to the adjacent first light-sensing cell 110, third light-sensing cell 130, and fourth light-sensing cell 140.

In addition, similarly, the shape, size, and arrangement of the nano posts NP provided in each region of the color separation lens layer 200 may be determined so as to form a phase in which light of the third wavelength passing through the color separation lens layer 200 is focused onto the third light detection cell 130 and does not proceed to the adjacent first light detection cell 110, second light detection cell 120, and fourth light detection cell 140.

The color separation lens layer 200 may cause light immediately after passing through the color separation lens layer 200 to have the following target phase distribution. That is, at the position immediately after passing through the color separation lens layer 200, that is, at the lower surface of the color separation lens layer 200 or the upper surface of the spacer layer 300, the phase of the light of the first wavelength may exhibit 2Nπ at the center of the first region 210 corresponding to the first light sensing cell 110 and the center of the fourth region 240 corresponding to the fourth light sensing cell 140. In addition, (2N−1)π may be represented at the center of the second region 220 corresponding to the second light-sensing cell 120 and at the center of the third region 230 corresponding to the third light-sensing cell 130. Here, N is an integer greater than 0.

In other words, at the position immediately after passing through the color separation lens layer 200, the phase of light of the first wavelength may be at a relative maximum at the center of the first region 210 and the center of the fourth region 240, gradually decreases in a concentric shape as it moves away from the center of the first region 210 and the center of the fourth region 240, and may be at a relative minimum at the center of the second region 220 and the center of the third region 230. For example, when N=1, the phase of light of the first wavelength at the location where it has passed through the color separation lens layer 200 may be 2π at the center of the first region 210 and the center of the fourth region 240, and π at the center of the second region 220 and the center of the third region 230. Here, the phase may mean a relative phase value to the phase just before the light passes through the nano post (NP).

In addition, the phase of the light of the second wavelength at the position immediately after passing through the color separation lens layer 200 may be 2Mπ at the center of the second region 220 corresponding to the second light-sensing cell 120, and (2M−1)π at the center of the first region 210 corresponding to the first light-sensing cell 110 and the center of the fourth region 240 corresponding to the fourth light-sensing cell 140. Additionally, it may be greater than (2M-−2)π and less than (2M−1)π at the center of the third region 230 corresponding to the third light-detecting cell 130. Here, M is an integer greater than 0. In other words, the phase of the light of the second wavelength at the position immediately after passing through the color separation lens layer 200 may be maximum at the center of the second region 220, gradually decrease in a concentric shape as it moves away from the center of the second region (220), and be locally minimized at the centers of the first region 210, the fourth region (240), and the third region 230. For example, when M=1, the phase of light of the second wavelength at the location where it has passed through the color separation lens layer 200 may be 2π at the center of the second region 220, π at the center of the first region 210 and the center of the fourth region 240, and about 0.2π to 0.7π at the center of the third region 230.

Likewise, the phase of light of the third wavelength at the position immediately after passing through the color separation lens layer 200 may be 2Lπ at the center of the third region 230 corresponding to the third light-sensing cell 130, (2L−1)π at the center of the first region 210 corresponding to the first light-sensing cell 110 and the fourth region 240 corresponding to the fourth light-sensing cell 140, and may be greater than (2L−2)π and less than (2L−1)π at the center of the second region 220 corresponding to the second light-sensing cell 120. Here, L is an integer greater than 0. In other words, the phase of light of the third wavelength at the position immediately after passing through the color separation lens layer 200 may be maximum at the center of the third region 230, and gradually decrease in the concentric shape as it moves away from the center of the third region 230, and be locally minimized at the centers of the first region 210, the fourth region 240, and the second region 220. For example, when L=1, the phase of the third wavelength at the position where it passes through the color separation lens layer 200 may be 2π at the center of the third region 230, π at the center of the first region 210 and the center of the fourth region 240, and about 0.2π to 0.7π at the center of the second region 220.

The light of the first wavelength, the light of the second wavelength, and the light of the third wavelength may be a green light, a blue light, and a red light, respectively. But the example embodiments are not limited to this. As mentioned above, the target phase distribution may mean the phase distribution at the position immediately after passing through the color separation lens layer 200. In addition, when light of this phase distribution travels toward the plurality of light detection cells 110, 120, 130, and 140), the light may form the different wavelength spectra depending on the distance traveled.

Then, a method for manufacturing the image sensor according to one embodiment will be described below with reference to drawings. FIGS. 18 to 21 are cross-sectional views schematically showing a process of a method for manufacturing an image sensor according to one embodiment of the present disclosure. It is described with reference to FIG. 2 and FIG. 3 together, and the contents already explained above are briefly explained or omitted.

Referring to FIG. 18, a sensor substrate 100 is provided and a spacer layer 300 are formed on the sensor substrate 100. The sensor substrate 100 may include a plurality of light-sensitive cells. The descriptions of the sensor substrate 100 and the spacer layer 300 are the same as those described above and are therefore omitted.

Afterwards, an intermediate layer 500 is formed on the spacer layer (300). The intermediate layer 500 may include Al₂O₃, but it is not limited thereto. According to at least one example embodiment, the intermediate layer 500 may be omitted.

Next, a dielectric material layer for the dielectric layer 205 is formed on the intermediate layer 500. The dielectric material layer may include a low refractive index material, such as SiO₂. However, the material of the dielectric layer is not limited to SiO₂. Subsequently, a photoresist (PR) pattern may be formed on the dielectric material layer through a photo process, and the dielectric material layer may be etched using the PR pattern as a mask to form a dielectric layer 205. At this time, a plurality of openings OP may be formed in the dielectric layer 205. As illustrated in FIG. 18, the widths of the plurality of openings OP may vary. The width D3 of the opening OP is shown in FIG. 18.

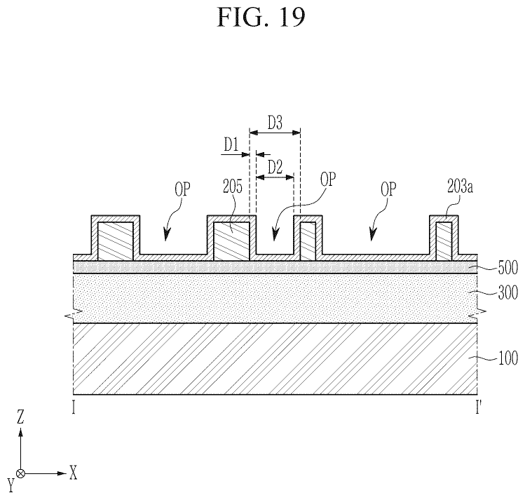

Next, referring to FIG. 19, after the formation of the dielectric layer 205, a second material layer 203a covering the intermediate layer 500 and the dielectric layer 205 is formed. The second material layer 203a may be formed to a very thin thickness through an ALD (Atomic Layer Deposition) process. For example, the thickness D1 of the second material layer 203a may be 5 nm to 30 nm.

The second material layer 203a may include a material having a refractive index equal to or higher than that of the dielectric layer 205. The second material layer (203a) may include the same material as the dielectric layer (205), and may include SiO₂, for example. Alternatively, the second material layer 203a may include SiO₂ or Al₂O₃. However, these materials are only examples and the present disclosure is not limited thereto.

Since the second material layer 203a is formed on both sides of the opening OP as in FIG. 19, the width D2 of the opening OP is reduced by the thickness D1 of the second material layer 203a from the width D3 formed in FIG. 13.

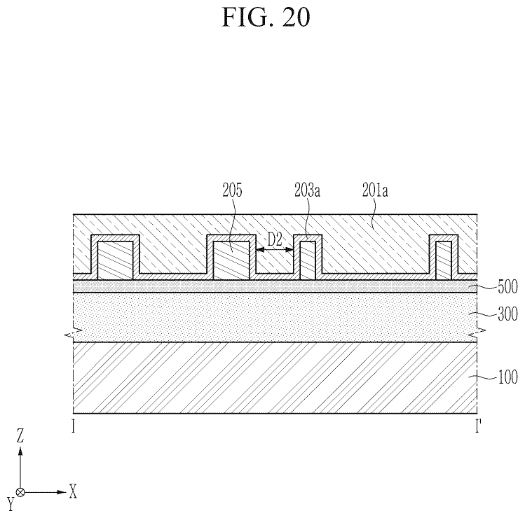

Next, referring to FIG. 20, after forming the second material layer 203a, a first material layer 201a covering the second material layer 203a is formed. The first material layer 201a may be formed with a relatively high thickness. For example, the first material layer 201a may be formed with the thickness that can completely fill the groove formed by the dielectric layer 205 and the second material layer 203a. The first material layer 201a may be formed of a material having an excellent light transmittance and a high refractive index. The refractive index of the first material layer 201a may be higher than the refractive index of the second material layer 203a. Additionally, the refractive index of the first material layer 201a may be higher than the refractive index of the dielectric layer 205. For example, the first material layer 201a may be formed of TiO₂. However, this is just one example and the first material layer 201a may include any one of SiN₃, Si₃N₄, ZnS, GaN, ZnSe, TiO₂, and hydrogen-doped amorphous silicon (a-Si:H). The width D2 of the first material layer 201a in the area where the opening was located may be 50 nm to 250 nm.

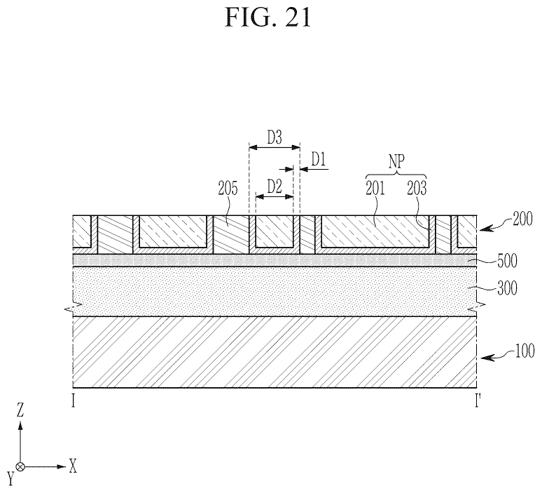

Next, referring to FIG. 21, after the first material layer 201a is formed, nano posts NP are formed through a CMP process. In the CMP process, the dielectric layer 205 may act as an etch stop film. Through the CMP process, the first material layer 201a may be separated into a plurality of first refractive layers 201, and also, the second material layer 203a may be separated into a plurality of second refractive layers 203. The separated first refractive layers 201 and second refractive layers 203 may form the nano posts NP.

The width D2 of the first refractive layer 201 in the formed nano post NP may be 50 nm to 250 nm. This is smaller than the width D3 of the opening OP formed in the previous patterning of the dielectric layer 205. That is, using this manufacturing method, it is possible to form the first refractive layer 201 having the narrower width than a finest pattern formed in the patterning of the dielectric layer 205.

As the resolution of the image sensors increases, the size of each pixel decreases, and the size of the individual nano post NP needs to be formed smaller. However, the process of forming these fine patterns is not easy. Since the formation of the nano post NP is performed after the formation of the sensor substrate 100, it is difficult to use a high temperature process of 250° C. or higher during the formation process of the nano post NP. Therefore, there are limitations in selecting a hard mask to form the fine pattern.

However, in at least one example embodiment, after forming and patterning the dielectric layer 205, the second refractive layer 203 is formed by the ALD. Accordingly, the width of the formed opening OP is reduced by the thickness of the second refractive layer 203, and the first refractive layer 201 having the small width may be formed.

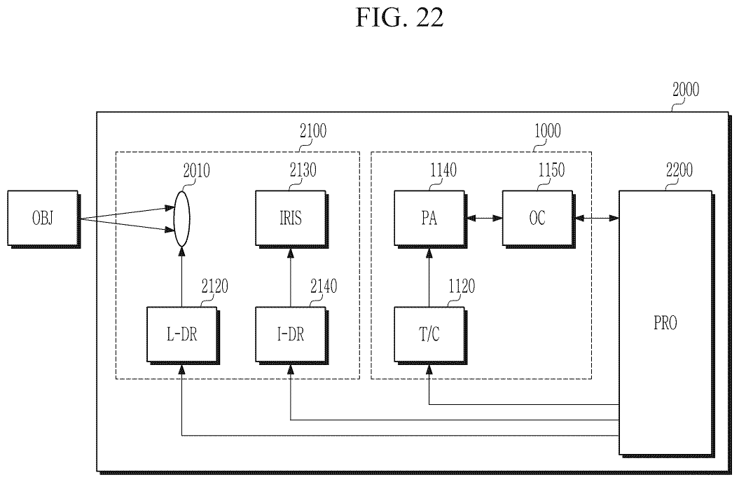

FIG. 22 is a block diagram of an electronic device including an image sensor according to one embodiment of the present disclosure. The following description is provided together with reference to FIG. 1, and any previously explained content is briefly explained or omitted.

Referring to FIG. 22, an electronic device 2000 including an image sensor of at least one example embodiment may include an imaging unit 2100, an image sensor 1000, and a processor 2200. The electronic device 2000 may be, for example, a camera. The imaging unit 2100 may form an optical image by focusing light reflected from an object OBJ. The imaging unit 2100 may include an objective lens 2010, a lens driver 2120, an aperture 2130, and an aperture driver 2140. In FIG. 22, only one lens is shown for convenience, but the example embodiments are not limited thereto, and the objective lens (2010) may include multiple lenses of different sizes and shapes. In some example embodiments, the electronic device (2000) may be a mobile camera, and in the mobile camera, the aperture (2130) and the aperture driver (2140) may be omitted.

The lens driving unit 2120 may communicate an information regarding a focus detection with the processor 2200 and adjust the position of the objective lens 2010 according to a control signal provided from the processor 2200. The lens drive unit 2120 may move the objective lens 2010 to adjust the distance between the objective lens 2010 and the subject OBJ, or may adjust the positions of individual lenses (not shown) within the objective lens 2010. The focus on the object OBJ may be adjusted by driving the objective lens 2010 by using the lens driving unit 2120. This electronic device 2000 may have an autofocus function.

The aperture driver 2140 may communicate the information about the amount of light with the processor 2200 and adjust the aperture 2130 according to the control signal provided from the processor 2200. For example, the aperture drive unit 2140 may increase or decrease the diameter of the aperture 2130 depending on the amount of light entering the interior of the electronic device 2000 through the objective lens 2010. Additionally, the aperture drive unit 2140 can adjust the opening time of the aperture (2130).

The image sensor 1000 may generate an electrical image signal based on the intensity of an incident light. The image sensor 1000 may be, for example, the image sensor 1000 of FIG. 1. Accordingly, the image sensor 1000 may include a pixel array 1140, a timing generator 1120, and a readout circuit 1150. Light passing through the objective lens 2010 and the aperture 2130 may form the image of the object OBJ on the light-receiving surface of the pixel array 1100. The pixel array 1100 may be a CCD or CMOS that converts an optical signal into an electrical signal. The pixel array 1100 may include additional pixels for performing an AF function or a distance measurement function.

The processor 2200 may control the overall operation of the electronic device 2000 and may have an image processing function.

For example, the processor 2200 may provide control signals for the operation of each component, such as the lens driver 2120, the aperture driver 2140, and the timing generator 1120.

In at least one example embodiment, a manufacturing method of an image sensor includes pattering a dielectric layer to form an opening, forming a second material layer on the opening and the dielectric layer, and forming a first material layer on the second material, wherein the refractive index of the first material layer may be greater than the refractive index of the second material.

Forming the second material layer may be performed by an ALD process.

The thickness of the second material may be 5 nm to 30 nm.

The refractive index of the second material layer may be greater than the refractive index of the dielectric layer.

The second material layer may include the same material as the dielectric layer.

The method may further include performing a CMP process on the second material layer and the first material layer to form nano posts, and the width of the first material layer included in the nano posts may be smaller than the width of the opening formed in forming the opening by patterning the dielectric layer.

The width of the first material layer may be 50 nm to 250 nm.

The second material layer may be positioned along the bottom surface and side surface of the first material layer.

The dielectric layer may include SiO₂, and the first material layer include titanium oxide (TiO₂).

While this disclosure has been described in connection with what is presently considered to be practical example embodiments, it is to be understood that the disclosure is not limited to the disclosed embodiments, but, on the contrary, is intended to cover various modifications and equivalent arrangements included within the spirit and scope of the appended claims.

What is claimed is:

1. An image sensor comprising:
a sensor substrate including a photoelectric conversion region;
a spacer layer on the sensor substrate; and
a color separation lens layer spaced apart from the sensor substrate with the spacer layer between the sensor substrate and the color separation lens layer,
wherein the color separation lens layer includes a plurality of nano posts and a dielectric layer between the plurality of nano posts,
each of the plurality of nano posts include a first refraction layer and a second refraction layer,
the second refraction layer is positioned along a bottom surface of the first refraction layer and a side surface of the first refraction layer, and
a refractive index of the first refraction layer is larger than a refractive index of the second refraction layer.

2. The image sensor of claim 1, wherein:
the refractive index of the second refraction layer is larger than a refractive index of the dielectric layer.

3. The image sensor of claim 1, wherein:
the second refraction layer includes a same material as the dielectric layer.

4. The image sensor of claim 1, wherein:
a thickness of the second refraction layer is 5 nanometers (nm) or more and 30 nm or less.

5. The image sensor of claim 1, wherein:
a maximum width of the first refraction layer is 50 nanometers (nm) or more and 250 nm or less.

6. The image sensor of claim 1, wherein:
the color separation lens layer is a first color separation lens layer, and
wherein the image sensor further includes a second color separation lens layer overlapped with the first color separation lens layer, and the second color separation lens layer includes a plurality of nano posts and a second dielectric layer between the plurality of nano posts of the second color separation lens layer.

7. The image sensor of claim 6, wherein:
the plurality of nano posts of the first color separation lens layer and the second color separation lens layer each include a first refractive layer, and
the plurality of nano posts of the first color separation lens layer further including a second refractive layer surrounding the first refractive layer of the first color separation lens layer, a refractive index of the first refractive layer is greater than a refractive index of the second refractive layer.

8. The image sensor of claim 6, wherein:
the plurality of nano posts of the first color separation lens layer include a first refractive layer and a second refractive layer surrounding the first refractive layer, the refractive index of the first refractive layer is greater than the refractive index of the second refractive layer, and the plurality of nano posts included in the second color separation lens layer include a third refractive layer and a fourth refractive layer surrounding the third refractive layer, and a refractive index of the third refractive layer is lower than a refractive index of the fourth refractive layer.

9. An image sensor comprising:
a sensor substrate including a photoelectric conversion region;
a spacer layer above the sensor substrate;
an intermediate layer above the spacer layer such that the spacer layer is between the intermediate layer and the sensor substrate; and
a color separation lens layer above the intermediate layer such that the intermediate layer is between the color separation lens layer and the spacer layer,
wherein the color separation lens layer includes a plurality of nano posts and a dielectric layer between the plurality of nano posts,
the plurality of nano posts each include a first refraction layer and a second refraction layer,
the second refraction layer covers a bottom surface and a side surface of the first refraction layer, and
a refractive index of the first refraction layer is greater than a refractive index of the second refraction layer and a refractive index of the dielectric layer.

10. The image sensor of claim 9, wherein:
a bottom surface of the second refraction layer is on the intermediate layer.

11. The image sensor of claim 9, wherein:
a bottom surface of the second refraction layer is within the intermediate layer, and
a portion of a side surface of the second refraction layer is in direct contact with the intermediate layer.

12. The image sensor of claim 9, wherein:
the plurality of nano posts penetrate the intermediate layer such that a bottom surface of the second refraction layer is within the spacer layer.

13. The image sensor of claim 9, wherein:
the intermediate layer includes aluminum oxide (Al₂O₃).

14. The image sensor of claim 9, wherein:
the refractive index of the second refraction layer is greater than the refractive index of the dielectric layer.

15. The image sensor of claim 9, wherein:
the second refraction layer includes the same material as the dielectric layer.

16. An image sensor comprising:
a sensor substrate including a photoelectric conversion region;
a spacer layer above the sensor substrate; and
a color separation lens layer above the spacer layer such that the spacer layer is between the color separation lens layer and the sensor substrate,
wherein the color separation lens layer includes a plurality of nano posts and a dielectric layer between the plurality of nano posts,
each of the plurality of nano posts include a first refraction layer,
the dielectric layer is on a bottom surface of the first refraction layer and on a side surface of the first refraction layer, and
a distance between a bottom surface of the dielectric layer and the spacer layer is less than a distance between the bottom surface of the first refraction layer and the spacer layer.

17. The image sensor of claim 16, wherein:
a refractive index of the first refraction layer is greater than a refractive index of the dielectric layer.

18. The image sensor of claim 16, wherein:
the distance between the bottom surface of the first refraction layer and the spacer layer is 5 nanometers (nm) or more and 30 nm or less.

19. The image sensor of claim 16, wherein:
a maximum width of the first refraction layer is 50 nanometers (nm) or more and 250 nm or less.

20. The image sensor of claim 16, wherein:
the dielectric layer includes silicon oxide (SiO₂), and
the first refraction layer includes titanium oxide (TiO₂).
